(19) United States
(12) Patent Application Publication
(10) Pub. No.: US 2026/0040697 A1
(43) Pub. Date: Feb. 5, 2026

(54) IMAGE SENSOR DEVICE AND METHOD OF FORMING THE SAME

(71) Applicant: Taiwan Semiconductor Manufacturing Company, Ltd., Hsinchu (TW)

(72) Inventors: Chun-Liang Lu, Tainan City (TW); Wei-Lin Lin, Hsinchu (TW); Chun-Hao CHOU, Tainan City (TW); Kuo-Cheng LEE, Tainan City (TW)

(73) Assignee: Taiwan Semiconductor Manufacturing Company, Ltd., Hsinchu (TW)

(21) Appl. No.: 18/790,309

(22) Filed: Jul. 31, 2024

(51) Int. Cl. H01L 27/146

(52) U.S. Cl. CPC H10F 39/014; H10F 39/18; H10F 39/199; H10F 39/807; H10F 39/809; H10F 39/811

(57) ABSTRACT

A method of forming a pixel array, includes: providing a substrate having a frontside and a backside; forming a recess in the frontside of the substrate for a front-side deep trench isolation (FDTI) feature; partially filling the recess with a sacrificial structure; forming an epitaxial grown silicon region in a top portion of the recess above the sacrificial structure and on the frontside of the substrate; forming a vertical transfer gate, photodetector, floating diffusion region, and p-well in the substrate; and completing the FDTI feature by replacing the sacrificial structure with a HK dielectric from the backside.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum feature sizes are reduced, additional problems arise that should be addressed.

### BRIEF DESCRIPTION OF DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a plan or layout view illustrating a CMOS image sensor (CIS), according to some embodiments.

FIG. 1B is a schematic cross sectional view of the pixel area of the CMOS image sensor, according to some embodiments.

FIG. 2 is a schematic cross sectional diagram depicting an example sub-pixel region of a back-illuminated stacked sensor with inter-pixel and inter-node isolation, according to some embodiments.

FIG. 3 is a flow diagram of an example method for fabricating a CIS device, according to some embodiments.

FIGS. 4-21 are schematic cross sectional diagram depicting an example CIS device at various stages of fabrication, according to some embodiments.

FIG. 22 is a schematic cross sectional diagram depicting an example sub-pixel region that is formed using an FDTI feature and a BDTI feature, according to some embodiments.

FIG. 23 is a schematic cross sectional diagram depicting an example sub-pixel region that is formed using an FDTI feature and a BDTI feature, according to some embodiments.

FIG. 24 is a schematic cross sectional diagram depicting an example sub-pixel region that is formed using an FDTI feature and a BDTI feature, according to some embodiments.

FIG. 25 is a schematic cross sectional diagram depicting example dimensions in an example sub-pixel region that is formed using an FDTI feature, according to some embodiments.

FIG. 26 is a schematic cross sectional diagram depicting example dimensions in an example sub-pixel region that is formed using a first BDTI feature and a second BDTI feature, according to some embodiments.

FIG. 27 is a schematic top view of a pixel, according to some embodiments.

FIG. 28 is a schematic top view of a first pixel and a second pixel, according to some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting.

For the sake of brevity, techniques related to conventional semiconductor device fabrication may not be described in detail herein. Moreover, the various tasks and processes described herein may be incorporated into a more comprehensive procedure or process having additional functionality not described in detail herein. In particular, various processes in the fabrication of semiconductor devices are well-known and so, in the interest of brevity, many conventional processes will only be mentioned briefly herein or will be omitted entirely without providing the well-known process details. As will be readily apparent to those skilled in the art upon a complete reading of the disclosure, the structures disclosed herein may be employed with a variety of technologies, and may be incorporated into a variety of semiconductor devices and products. Further, it is noted that semiconductor device structures include a varying number of components and that single components shown in the illustrations may be representative of multiple components.

Furthermore, spatially relative terms, such as “over”, “overlying”, “above”, “upper”, “top”, “under”, “underlying”, “below”, “lower”, “bottom”, and the like, may be used herein for ease of description to describe one element's or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. When a spatially relative term, such as those listed above, is used to describe a first element with respect to a second element, the first element may be directly on the other element, or intervening elements or layers may be present.

In addition, the present disclosure may repeat reference numerals and/or letters in the various examples. This repetition is for the purpose of simplicity and clarity and does not in itself dictate a relationship between the various embodiments and/or configurations discussed.

It is noted that references in the specification to “one embodiment,” “an embodiment,” “an example embodiment,” “exemplary,” “example,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to affect such feature, structure, or characteristic in connection with other embodiments whether or not explicitly described.

It is to be understood that the phraseology or terminology herein is for the purpose of description and not of limitation, such that the terminology or phraseology of the present specification is to be interpreted by those skilled in relevant art(s) in light of the teachings herein.

The following disclosure provides many different embodiments, or examples, for implementing different features of the disclosed subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. Throughout the description herein, unless otherwise specified, the same reference numeral in different figures refers to the same or similar component formed by a same or similar method using a same or similar material(s).

As used herein, the terms such as “first,” “second” and “third” describe various elements, components, regions, layers and/or sections, these elements, components, regions, layers and/or sections should not be limited by these terms. These terms may be only used to distinguish one element, component, region, layer, or section from another. The terms such as “first,” “second” and “third” when used herein do not imply a sequence or order unless clearly indicated by the context.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation of less than or equal to +10% of that numerical value, such as less than or equal to +5%, less than or equal to +4%, less than or equal to +3%, less than or equal to +2%, less than or equal to +1%, less than or equal to +0.5%, less than or equal to +0.1%, or less than or equal to +0.05%. For example, two numerical values can be deemed to be “substantially” the same or equal if a difference between the values is less than or equal to +10% of an average of the values, such as less than or equal to +5%, less than or equal to +4%, less than or equal to +3%, less than or equal to +2%, less than or equal to +1%, less than or equal to +0.5%, less than or equal to +0.1%, or less than or equal to +0.05%. For example, “substantially” parallel can refer to a range of angular variation relative to 0° that is less than or equal to +10°, such as less than or equal to +5°, less than or equal to +4°, less than or equal to +3°, less than or equal to +2°, less than or equal to +1°, less than or equal to +0.5°, less than or equal to +0.1°, or less than or equal to +0.05°. For example, “substantially” perpendicular can refer to a range of angular variation relative to 90° that is less than or equal to +10°, such as less than or equal to +5° less than or equal to +4°, less than or equal to +3°, less than or equal to +2°, less than or equal to +1°, less than or equal to +0.5°, less than or equal to +0.1°, or less than or equal to +0.05°.

Semiconductor image sensors are used to sense incoming visible or non-visible radiation, such as visible light, infrared light, etc. Complementary metal-oxide-semiconductor (CMOS) image sensors (CIS) are used in various applications, such as digital still cameras, mobile phones, tablets, goggles, etc. These image sensors utilize an array of pixels that absorb (e.g., sense) the incoming radiation and convert it into electrical signals.

A backside illumination (BSI) image sensor is a type of CIS device. A BSI image sensor includes a pixel region with an array of pixels or radiation-sensing regions formed on a substrate (e.g., a semiconductor substrate). The terms “radiation-sensing regions” and “pixels” may be used interchangeably throughout this disclosure. The pixels are configured to convert photons from the incident radiation to an electrical signal. The electrical signal is subsequently distributed to processing components attached to the BSI image sensor. For this reason, the pixel region overlies an interconnect structure in a multilevel metallization layer configured to distribute the electrical signal generated within the pixels to appropriate processing components. The multilevel metallization layer is formed on a first surface of the substrate. The pixel region is formed on a second surface of the substrate that is opposite to the first surface of the substrate. The pixel region includes a grid structure that provide optical isolation between adjacent pixels. Further, the pixel region includes color filtering layers. The material of color filtering layers can be selected such that light with a desired wavelength passes through the color filtering layers, while light with other wavelengths is absorbed by the color filtering layers.

A challenge with small pixels are to maintain dynamic range (DR), signal-to-noise ratio (SNR), and sensitivity compatible with a sensor with larger pixels. In accordance with some embodiments of the present disclosure, a back-illuminated stacked sensor with front deep-trench isolation (FDTI) for inter-pixel and inter-node isolation are provided for continuous pixel-size reduction in terms of maximizing DR with large full-well capacity (FWC) while minimizing optical/electrical crosstalk. In accordance with some embodiments of the present disclosure, FDTI structures are used for isolation instead of STI structures which can make fabrication easier. In accordance with some embodiments of the present disclosure, FDTI structures with a smaller critical dimension (CD) are used for isolation instead of back side deep trench isolation (BDTI) structures. In accordance with some embodiments of the present disclosure, FDTI structures are used which are etched from both the front side and the back side of the substrate. In accordance with some embodiments of the present disclosure, use of FDTI structures can lead to improved signal-to-noise ratio (SNR) with CIS sensors and less cross talk.

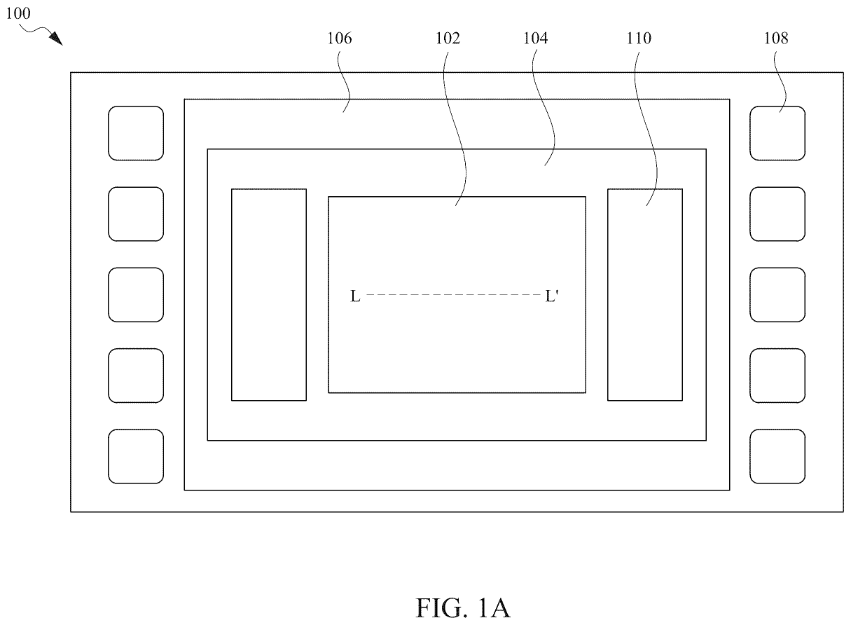

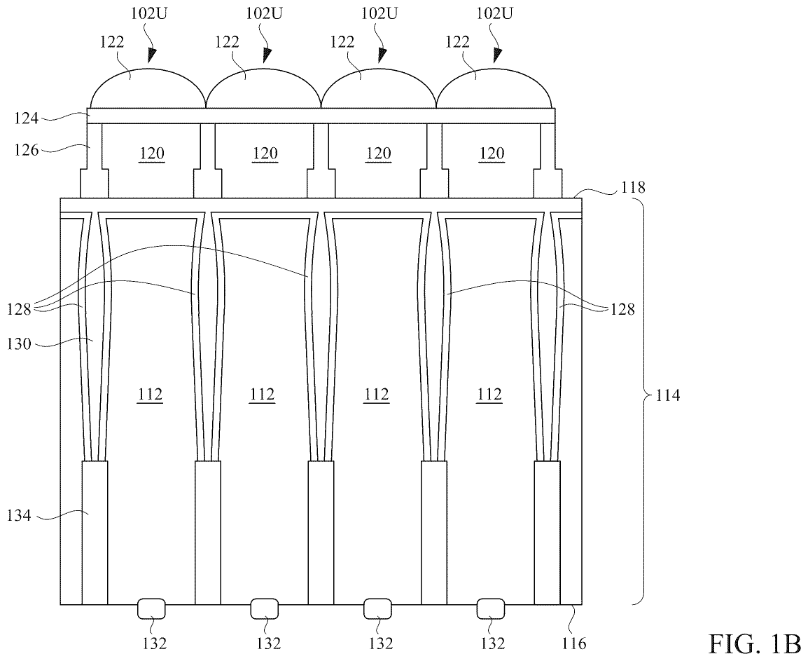

FIG. 1A is a plan or layout view illustrating an example CMOS image sensor (CIS) 100 according some embodiments. The example CMOS image sensor 100 include a pixel area 102 in which a plurality of unit pixels are arranged in a matrix, and an optical isolation region 104 surrounding the pixel area 102. Further, the optical isolation region 104 is surrounded by a physical isolation area 106. In some embodiments, the CMOS image sensor 100 includes a plurality of pad electrodes 108 for wiring to outside circuitry. The example CMOS image sensor 100 further includes one or more black level calibration (BLC) area 110 which blocks incident light and provide a reference dark voltage current.

FIG. 1B illustrates a cross sectional view of the pixel area 102 of the CMOS image sensor 100 along cutline L-L′ of FIG. 1A in the pixel area 102, in accordance with some embodiments. The pixel area 102 includes a plurality of unit pixels 102U, each of which includes a photodiode layer 112 formed in a semiconductor substrate 114 (e.g., Si substrate) having a first surface 116 and an opposing second surface 118, a color filter 120 disposed over the second surface 118 and substantially aligning with the photodiode layer 112, and a micro-lens 122 disposed over and aligning with the color filter 120. In some embodiments, a liner dielectric layer 124 is disposed between the color filter 120 and the micro-lens 122. The CMOS image sensor 100 also includes a first isolation structure 126 to laterally separate adjacent color filters 120. The example CMOS image sensor 100 includes a second isolation structure 128, which is a deep trench isolation structure filled with one or more dielectric materials 130, disposed in the semiconductor substrate 114 to laterally separate adjacent photodiode layers 112. In addition, the CMOS image sensor 100 includes a transfer gate 132 coupled to the photodiode layer 112 disposed on the first surface 116 of the substrate 114. In some embodiments, a third isolation structure 134, which is a doped region implanted with, for example, boron, is disposed between and aligning with the second isolation structure 128 and the first surface 116, and functions as an electrical isolation structure. In some embodiments, each unit pixel 102U has a square or a rectangular shape in plan view and is surrounded by the first isolation structure 126, second isolation structure 128, and third isolation structure 134.

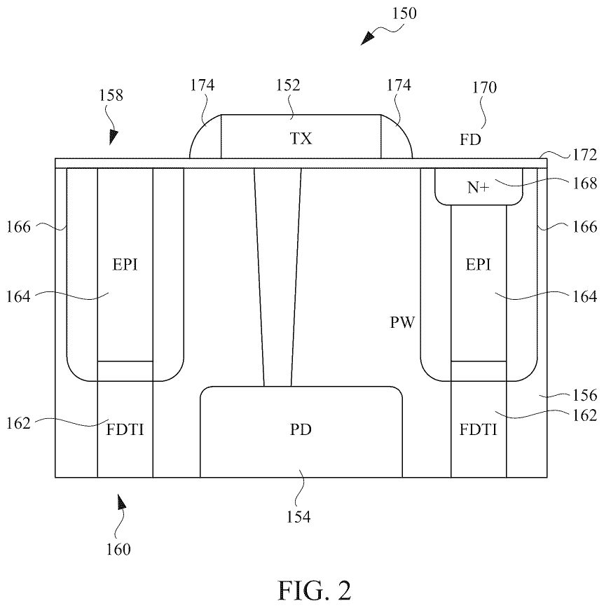

FIG. 2 is a schematic cross sectional diagram depicting an example sub-pixel region 150 of a back-illuminated stacked sensor with inter-pixel and inter-node isolation. In this example, the sub-pixel region 150 includes a gate poly region for a vertical transfer gate (VTG) 152 disposed above a photo detector 154 in a substrate 156 having a front side 158 and a back side 160. The substrate 156 may be a semiconductor substrate, such as a bulk semiconductor, a semiconductor-on-insulator (SOI) substrate, a semiconductor wafer, or the like, which may be doped (e.g., with a p-type or an n-type dopant) or undoped. Other substrates, such as a multi-layered or gradient substrate may also be used. In some embodiments, the semiconductor material of the substrate may include silicon.

The sub-pixel region 150 further includes a front side formed deep trench isolation (FDTI) feature 162 disposed in the substrate 156 on a side of the photo detector 154, an epitaxial grown silicon region (e.g., epitaxial layer or epi layer) 164 in the substrate 156 formed above the FDTI feature 162 on a first side of the VTG 152, and a p-well 166 disposed in the substrate 156 around the epitaxial grown silicon region 164. The sub-pixel region 150 also includes an n+ doped region 168 that forms a floating diffusion (FD) region 170, a pad oxide layer 172, and gate spacers 174.

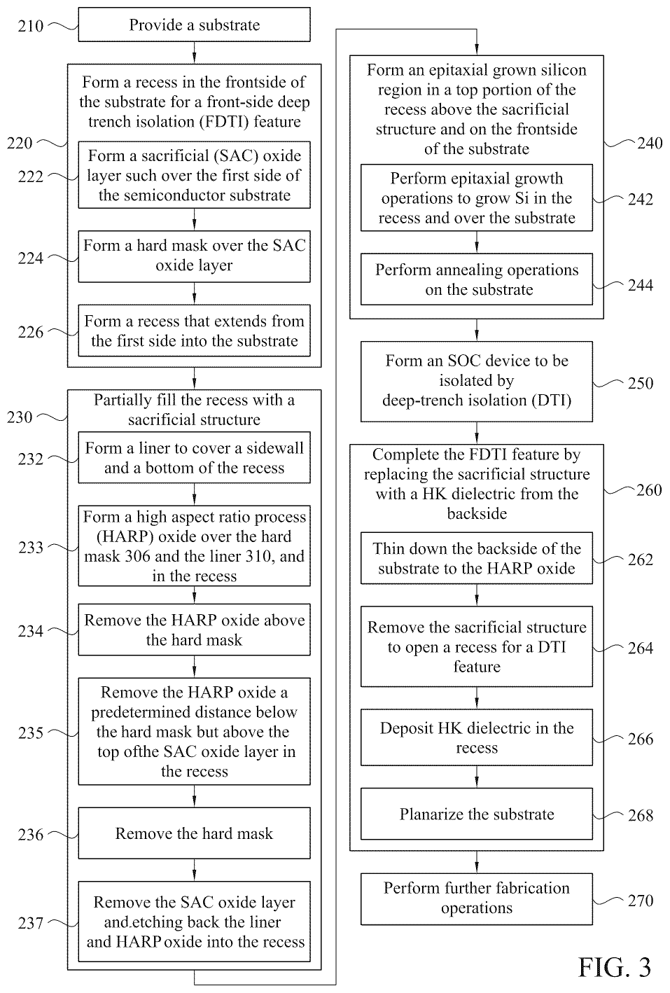

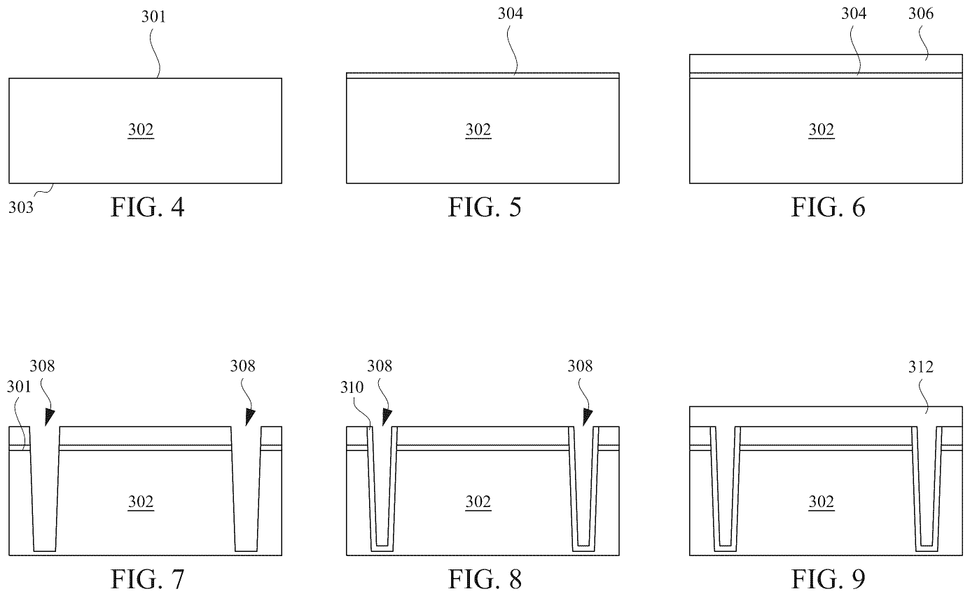

FIG. 3 is a flow diagram of an example method 200 for fabricating a CIS device (e.g., sub-pixel region 150), according to some embodiments. For illustrative purposes, the operations illustrated in FIG. 3 will be described with reference to FIGS. 4-21, which show cross-sectional views of a CIS device at various stages of its fabrication process, according to some embodiments. Operations can be performed in a different order or not performed depending on specific applications. It should be noted that method 200 may not produce a complete CIS device. Accordingly, it is understood that additional processes can be provided before, during, and after method, and that some other processes may only be briefly described herein. In some figures, some reference numbers of components or features illustrated therein may be omitted to avoid obscuring other components or features; this is for ease of depicting the figures.

The method 200 is merely an example, and is not intended to limit the present disclosure beyond what is explicitly recited in the claims. Additional steps may be provided before, during, and after example method 200, and some of the steps described can be moved, replaced, or eliminated for additional embodiments of example method 200. Additional features may be added in the semiconductor device depicted in the figures and some of the features described below can be replaced, modified, or eliminated in other embodiments of the semiconductor device.

It is understood that parts of the semiconductor device may be fabricated by typical semiconductor technology process flow, and thus some processes are only briefly described herein. Further, the exemplary semiconductor devices may include various other devices and features, such as other types of devices such as additional transistors, bipolar junction transistors, resistors, capacitors, inductors, diodes, fuses, and/or other logic devices, etc., but is simplified for a better understanding of concepts of the present disclosure. In some embodiments, the exemplary devices include a plurality of semiconductor devices (e.g., transistors), including PFETs, NFETs, etc., which may be interconnected. Moreover, it is noted that the operations of method 200, including any descriptions given with reference to the Figures are merely exemplary and are not intended to be limiting beyond what is specifically recited in the claims that follow.

At block 210, the method 200 includes providing a semiconductor substrate. Referring to the example of FIG. 4, in an embodiment of block 210, a semiconductor substrate 302 is provided. The semiconductor substrate 302 includes a first side 301, and a second side 303 opposite to the first side 301. In some embodiments, the first side 301 may be defined as a frontside of the semiconductor substrate 302, and the second side 303 may be defined as a backside of the semiconductor substrate 302.

At block 220, the method 200 includes forming a recess in the frontside of the substrate for a front-side deep trench isolation (FDTI) feature. In various embodiments, forming a recess in the frontside of the substrate for a front-side deep trench isolation (FDTI) feature includes operations identified at blocks 222, 224, and 226.

At block 222, the method 200 includes forming a sacrificial (SAC) oxide layer over the first side 301 of the semiconductor substrate 302. Referring to the example of FIG. 5, in an embodiment of block 222, a SAC oxide layer 304 such as a silicon oxide layer (e.g., SiO₂) is formed over the first side 301 of the semiconductor substrate 302.

At block 224, the method 200 includes forming a hard mask over the SAC oxide layer. Referring to the example of FIG. 6, in an embodiment of block 224, a hard mask 306 is formed over the SAC oxide layer 304.

At block 226, the method 200 includes forming a recess that extends from the first side 301 into the substrate 302. Referring to the example of FIG. 7, in an embodiment of block 226 a recess 308 is formed that extends from the first side 301 into the substrate 302. In some embodiments, the recess 308 is formed by photolithography and etching techniques. By way of example, the hard mask 306 may be patterned, such that a portion of the first side 301 of the semiconductor substrate 302 is exposed. In some embodiments, the hard mask 306 may be a multi-layered hard mask. By way of example, the material of the hard mask 306 may include silicon nitride (SIN). The semiconductor substrate 302 is then etched from the first side 301 using the hard mask 306 as an etch mask to form the recess 308.

At block 230, the method 200 includes partially filling the recess with a sacrificial structure. In various embodiments, partially filling the recess with a sacrificial structure includes operations identified at blocks 232, 233, 234, 235, 236, and 237.

At block 232, the method 200 includes forming a liner 310 to cover a sidewall and a bottom of the recess the recess 308. Referring to the example of FIG. 8, in an embodiment of block 232, a liner 310 is formed to cover a sidewall and a bottom of the recess 308. In some embodiments, a flowable dielectric material fills the recess 308 to form a flowable dielectric film. The flowable dielectric film may comprise a flowable silicon oxide material. In some embodiments, annealing is performed to convert the flowable dielectric film to the liner 310, which can also improve the quality of the liner. In some embodiments, the material of the liner 310 may include SiO₂.

At block 233, the method 200 includes forming a high aspect ratio process (HARP) oxide over the hard mask 306 and the liner 310, and in the recess 308. Referring to the example of FIG. 9, in an embodiment of block 233, a HARP oxide 312 is formed over the hard mask 306 and the liner 310, and in the recess 308. In some embodiments, the HARP oxide 312 is formed by a high aspect ratio process (HARP) alone or together with some high density plasma (HDP) CVD process other CVD techniques. In some embodiments, the material of the HARP oxide 312 may include SiO₂.

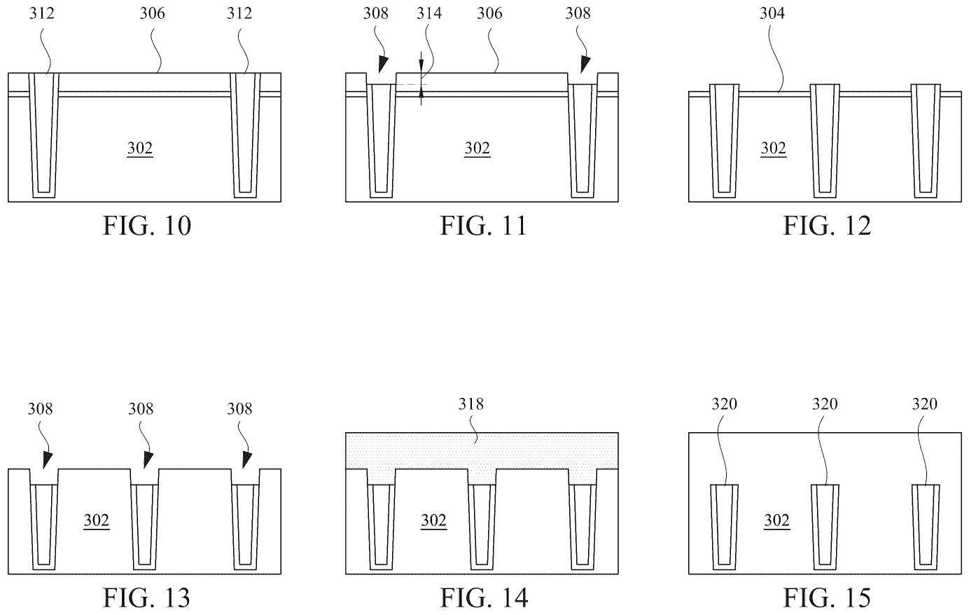

At block 234, the method 200 includes removing the HARP oxide 312 above the hard mask 306. In an embodiment, the HARP oxide 312 is removed above the hard mask 306 via chemical mechanical polishing (CMP) operations. Referring to the example of FIG. 10, in an embodiment of block 234, the HARP oxide 312 has been removed above the hard mask 306 via chemical mechanical polishing (CMP) operations.

At block 235, the method 200 includes removing the HARP oxide 312 a predetermined distance 314 below the hard mask 306 but above the top of the SAC oxide layer 304 in the recess 308. Referring to the example of FIG. 11, in an embodiment of block 235, HARP oxide 312 (and liner 310) has been removed a predetermined distance 314 below the hard mask 306. In some embodiments, a hydrogen Fluoride (HF) wet clean process in a wet bench is used to remove the HARP oxide 312 a predetermined distance 314 below the hard mask 306. In some embodiments, the predetermined distance is approximately 250 Angstroms (Å).

At block 236, the method 200 includes removing the hard mask 306. In various embodiments, the hard mask 306 is removed by wet etching operations in a wet bench process using an etchant such as an acid solution that includes metaphosphoric acid (HPO₃). Referring to the example of FIG. 12, in an embodiment of block 236, the hard mask 306 has been removed.

At block 237, the method 200 includes removing the SAC oxide layer 304 and etching back the liner 310 and HARP oxide 312 into the recess 308. Referring to the example of FIG. 13, in an embodiment of block 237, the SAC oxide layer 304 has been removed and the liner 310 and HARP oxide 312 have been etched back into the recess 308. In some embodiments, wet etching operations are used to remove the SAC oxide layer 304 and etch back the liner 310 and HARP oxide 312. This results in the formation of a sacrificial structure 320 comprising the remaining portion of the liner 310 and the HARP oxide 312.

At block 240, the method 200 includes forming an epitaxial grown silicon region in a top portion of the recess above the sacrificial structure and on the frontside of the substrate. In various embodiments, forming an epitaxial grown silicon region in a top portion of the recess above the sacrificial structure and on the frontside of the substrate includes operations identified at blocks 242 and 244.

At block 242, the method 200 includes epitaxial growth operations to grow Si in the recess 308 and over the substrate 302. Referring to the example of FIG. 14, in an embodiment of block 242, epitaxial grown Si regions 318 has been grown in the recess 308 and over the substrate 302.

At block 244, the method 200 includes annealing operations on the substrate. Referring to the example of FIG. 15, in an embodiment of block 244, the epitaxial grown Si regions 318 have been treated via annealing operations to be consistent with the rest of the silicon substrate.

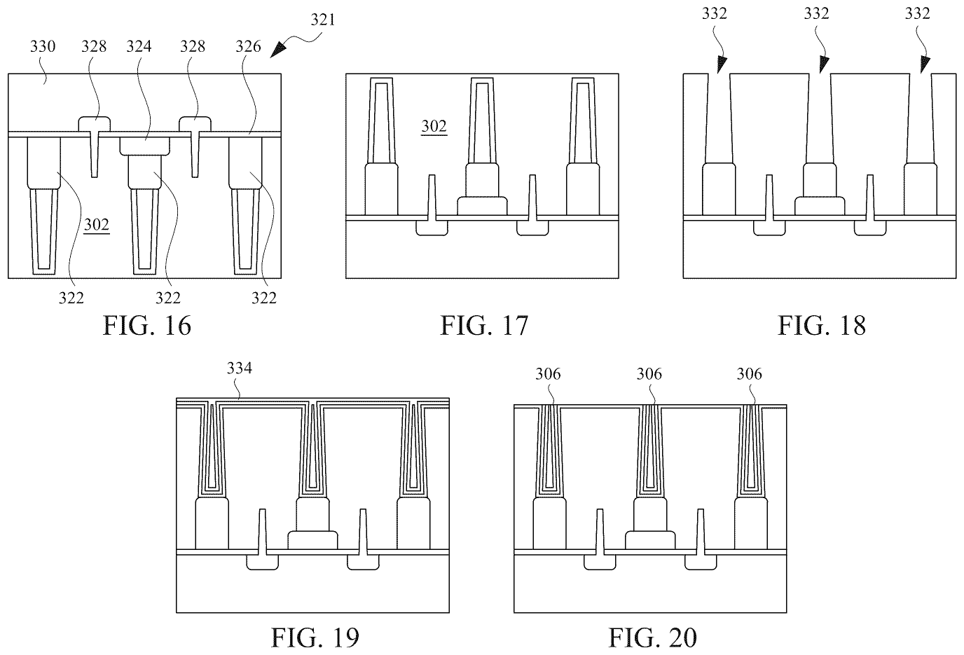

At block 250, the method 200 includes forming a CMOS image sensor (CIS) device to be isolated by deep-trench isolation (DTI). Referring to the example of FIG. 16, in an embodiment of block 250, an example CIS device 321 is formed. In various embodiments the CIS device 321 includes at least one p-well 322 formed above the sacrificial structure 320 and around a portion of the epitaxial grown Si regions 318, an n+ doped region 324 for a floating diffusion (FD) region that is formed above at least one p-well 322, a pad oxide layer 326 (e.g., similar to the SAC oxide layer 304) formed above the substrate 302, a gate poly region 328 for a transfer gate, and a photo detector (not shown). In various embodiments, an interconnect structure 330 comprising metallization layers and/or interlayer dielectric (ILD) layers is formed to connect the CIS device 321 to various circuits.

At block 260, the method 200 includes completing the FDTI feature by replacing the sacrificial structure with a HK dielectric from the backside. In various embodiments, completing the FDTI feature by replacing the sacrificial structure with a HK dielectric from the backside includes operations identified at blocks 242 and 244.

At block 262, the method 200 includes thinning down the backside of the substrate to the HARP oxide 312. Referring to the example of FIG. 17, in an embodiment of block 262, the substrate 302 is flipped over (e.g., ˜180°) and the backside of the substrate 302 (e.g., the second side 303) is thinned down to the level of the liner 310 in the sacrificial structure 320. In various embodiments, the backside of the substrate is thinned down using CMP operations.

At block 264, the method 200 includes removing the sacrificial structure to open a recess for a DTI feature. In various embodiments, the sacrificial structure is removed via wet etching operations. Referring to the example of FIG. 18, in an embodiment of block 264, the sacrificial structure 320 comprising the liner 310 and the HARP oxide 312 has been removed leaving a recess 332.

At block 266, the method 200 includes depositing HK dielectric in the recess 332. Referring to the example of FIG. 19, in an embodiment of block 266, a HK dielectric layer 334 has been deposited in the recess 332. In various embodiments, the HK dielectric layer 334 has been deposited by suitable deposition techniques.

At block 268, the method 200 includes planarizing the substrate. Referring to the example of FIG. 20, in an embodiment of block 268, an FDTI feature 336 has been formed by planarizing the substrate. In various embodiments, the substrate is planarized by CMP operations. This results in front side deep-trench isolation (FDTI) features 326 in the semiconductor substrate 302 for use in a back-illuminated stacked sensor for inter-pixel and inter-node isolation.

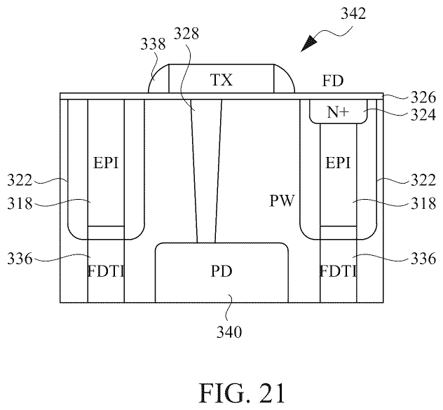

At block 270, the method 200 includes performing further fabrication operations to form the CIS device. FIG. 21 is a schematic cross sectional diagram depicting a sub-pixel region 342 of an example back-illuminated stacked sensor with inter-pixel and inter-node isolation. In this example, the sub-pixel region 342 includes at least one p-well 322 above the FDTI feature 336 and around a portion of the epitaxial grown Si regions 318, an n+ doped region 324, a pad oxide layer 326, a gate poly region 328 for a transfer gate, gate spacers 338, a FDTI feature 336, and a photo detector 340 (e.g., photo diode).

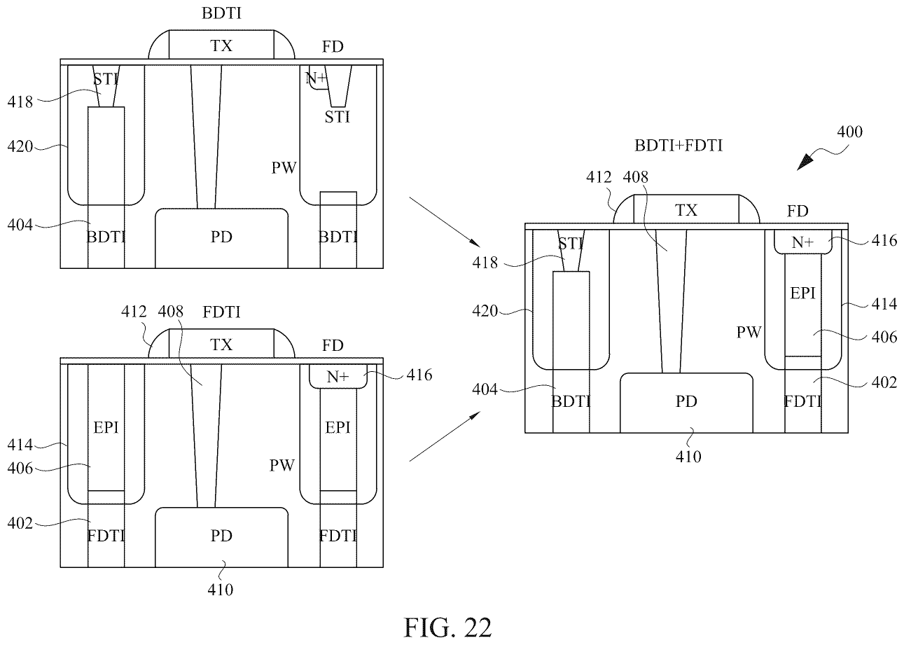

FIG. 22 is a schematic cross sectional diagram depicting an example sub-pixel region 400 that is formed using an FDTI feature 402 and a BDTI feature 404. In this example, techniques such as that illustrated by method 200 of FIG. 3 can be used to form the FDTI feature 402 in conjunction with suitable techniques for forming the BDTI feature 404 to provide isolation for the sub-pixel region 400. In various embodiments, the sub-pixel region 400 may be formed by forming the FDTI feature 402 and an epitaxial grown silicon feature 406 (e.g., using techniques illustrated by method 200) followed by forming a CIS device comprising a VTG 408, photo detector 410, gate spacers 412, a p-well 414, and a n+ doped region 416 and then by forming the BDTI feature 404, an STI feature 418, and a p-well 420.

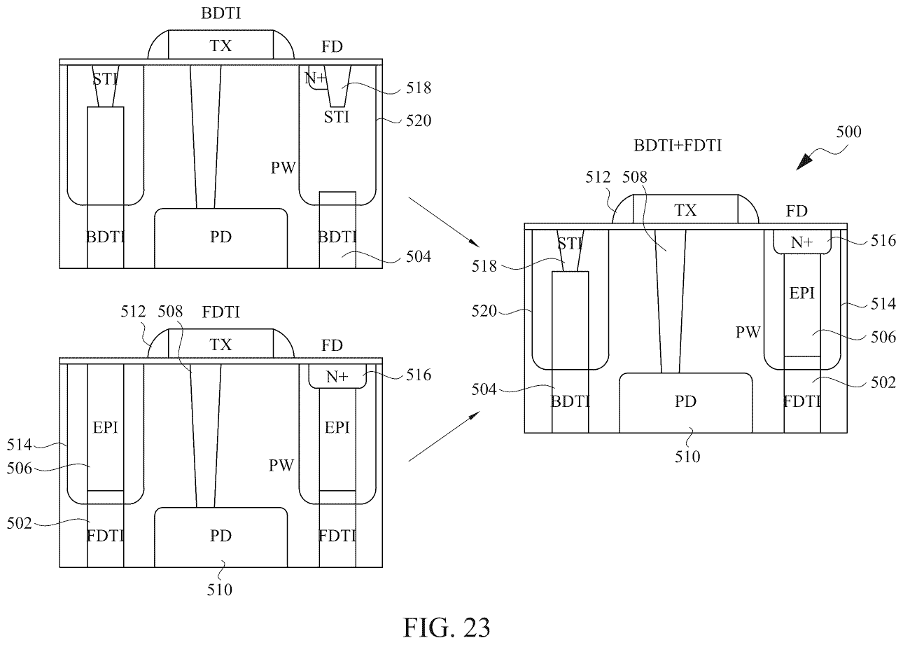

FIG. 23 is a schematic cross sectional diagram depicting an example sub-pixel region 500 that is formed using an FDTI feature 502 and a BDTI feature 504. In this example, techniques such as that illustrated by method 200 of FIG. 3 can be used to form the FDTI feature 502 in conjunction with suitable techniques for forming the BDTI feature 504 to provide isolation for the sub-pixel region 500. In various embodiments, the sub-pixel region 500 may be formed by forming the FDTI feature 502 and an epitaxial grown silicon feature 506 (e.g., using techniques illustrated by method 200) followed by forming a CIS device comprising a VTG 508, photo detector 510, gate spacers 512, a p-well 514, and a n+ doped region 516 and then by forming the BDTI feature 504, an STI feature 518, and a p-well 520.

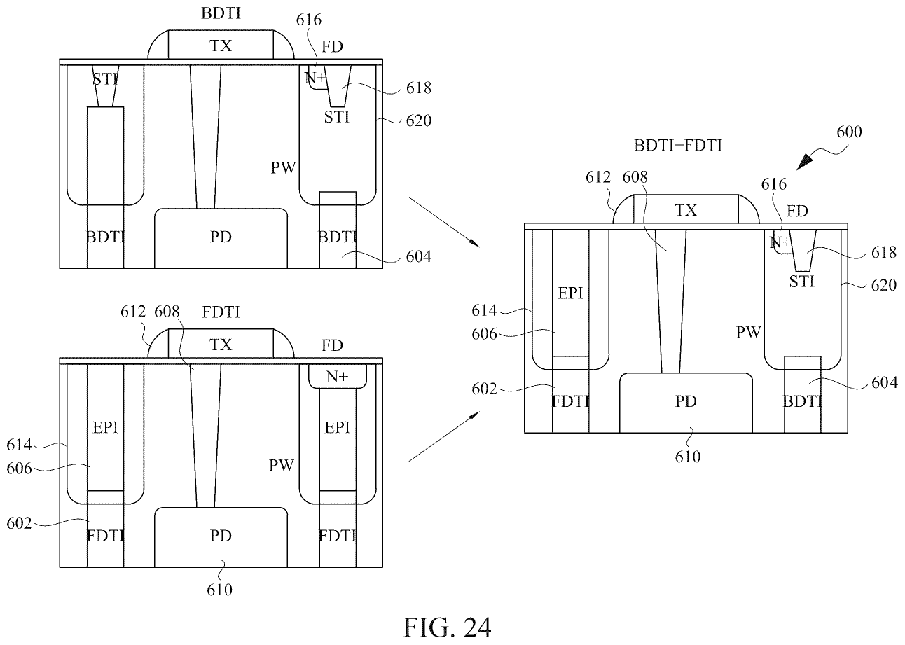

FIG. 24 is a schematic cross sectional diagram depicting an example sub-pixel region 600 that is formed using an FDTI feature 602 and a BDTI feature 604. In this example, techniques such as that illustrated by method 200 of FIG. 3 can be used to form the FDTI feature 602 in conjunction with suitable techniques for forming the BDTI feature 604 to provide isolation for the sub-pixel region 600. In various embodiments, the sub-pixel region 600 may be formed by forming the FDTI feature 602 and an epitaxial grown silicon feature 606 (e.g., using techniques illustrated by method 200) followed by forming a CIS device comprising a VTG 608, photo detector 610, gate spacers 612, a p-well 614, and a n+ doped region 616 and then by forming the BDTI feature 604, an STI feature 618, and a p-well 620.

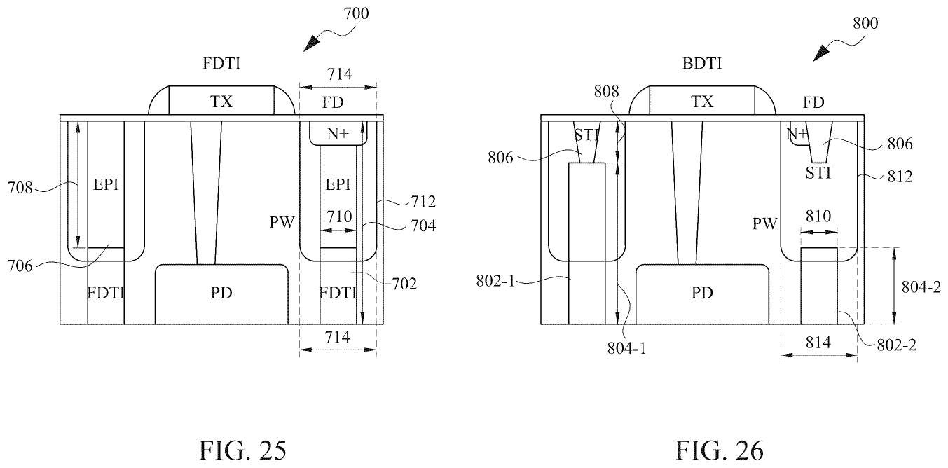

FIG. 25 is a schematic cross sectional diagram depicting example dimensions in an example sub-pixel region 700 that is formed using an FDTI feature 702. In various embodiments, the FDTI feature 702 has a depth 704 of approximately 2.5 micrometers to 3 micrometers. In various embodiments, an epitaxial grown silicon region (e.g., epitaxial layer or epi layer) 706 has a length 708 of approximately 150 nm to approximately 300 nanometers (nm). In various embodiments, the FDTI feature 702 (and epitaxial grown silicon region 706) has a critical dimension (CD) 710 of approximately 60 to approximately 90 nm. In various embodiments, a p-well 712 has a width 714 that is 0 to approximately 20 nm wider than the CD 710.

FIG. 26 is a schematic cross sectional diagram depicting example dimensions in an example sub-pixel region 800 that is formed using a first BDTI feature 802-1 and a second BDTI feature 802-2. In various embodiments, the first BDTI feature 802-1 has a depth 804-1 of approximately 2.7 micrometers to 2.9 micrometers. In various embodiments, the second BDTI feature 802-2 has a depth 804-2 of approximately 1.8 micrometers to 2.2 micrometers. In various embodiments, an STI feature 806 has a length 808 of approximately 100 nm to approximately 300 nanometers (nm). In various embodiments, the first BDTI feature 802-1 and the second BDTI feature 802-2 have a critical dimension (CD) 810 of approximately 110 to approximately 150 nm. In various embodiments, a p-well 812 has a width 814 that is 0 to approximately 10 nm wider than the CD 810. FIGS. 25 and 26 illustrate that the FDTI features can be fabricated with a CD that is smaller than the CD of the BDTI features.

FIGS. 25 and 26 illustrate that when an FDTI feature is used instead of a BDTI feature, STI is not required for inter-pixel isolation. As illustrated in FIG. 25, inter-pixel isolation can be achieved by using the FDTI feature 702, whereas, as illustrated in FIG. 26, inter-pixel isolation may be accomplished by using an STI feature 806 in connection with the first BDTI feature 802-1 and the second BDTI feature 802-2.

FIGS. 25 and 26 also illustrate that when an FDTI feature is used instead of a BDTI feature, a smaller critical dimension (CD) can be achieved for the isolation structures. As illustrated in FIG. 25, the CD of the FDTI feature 702 may be in the range of approximately 60 to approximately 90 nm, whereas, as illustrated in FIG. 26, the first BDTI feature 802-1 and the second BDTI feature 802-2 may have a CD of approximately 110 to approximately 150 nm. This can also result in the P-well 712 having a smaller width than the P-well 812. The smaller CD with FDTI feature 702 can allow for greater pixel density than with the first BDTI feature 802-1 and the second BDTI feature 802-2.

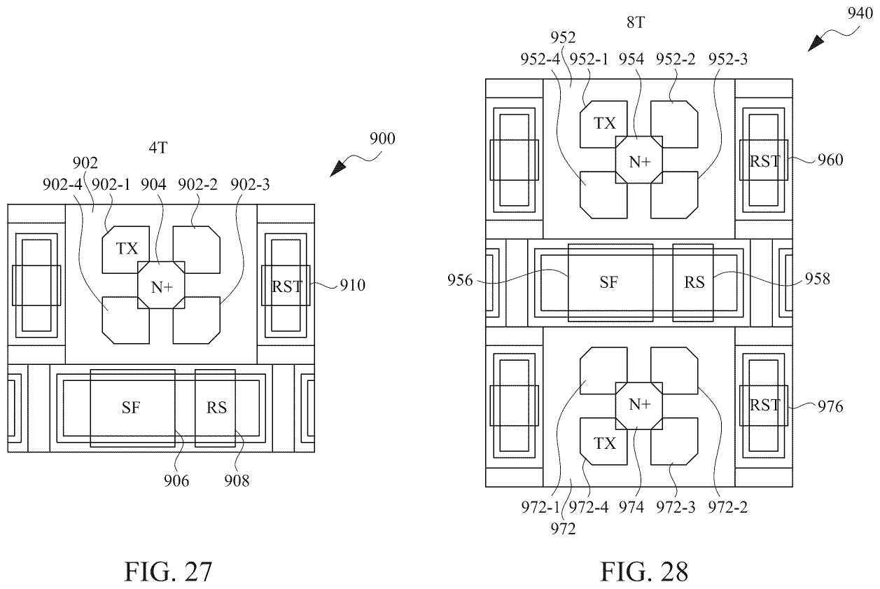

FIG. 27 is a schematic top view of a pixel 902 according to some embodiments of the present disclosure. The illustrated pixel 902 is in a so-called 4T configuration. As illustrated the pixel 902 has four sub-pixels (902-1, 902-2, 902-3, 902-4). However, the disclosure is not limited thereto. In some alternative embodiments, a pixel 902 may have three sub-pixels, or more than three sub-pixels depending on design requirement.

In the exemplary embodiment, the first sub-pixel 902-1 includes a first photo sensing region located within the substrate 900, and a first transfer gate (e.g., VTG 152) extending into the first photo sensing region. The second sub-pixel 902-2 includes a second photo sensing region located within the substrate 900, and a second transfer gate extending into the second photo sensing region. The third sub-pixel 902-3 includes a third photo sensing region located within the substrate 900, and a third transfer gate extending into the third photo sensing region. Similarly, the fourth sub-pixel 902-4 includes a fourth photo sensing region located within the substrate 900, and a fourth transfer gate extending into the fourth photo sensing region. In some embodiments, the photo sensing regions in each of the sub-pixels (902-1, 902-2, 902-3, 902-4) may be formed in the same steps. Furthermore, the transfer gates in each of the sub-pixels (902-1, 902-2, 902-3, 902-4) may be formed in the same steps.

In the exemplary embodiment, a floating diffusion (FD) region 904 is shared between the first photo sensing region, the second photo sensing region, the third photo sensing region and the fourth photo sensing region. In other words, the image charges accumulated in each of the photo sensing regions may be transferred to the same FD region 904 for readout. In some embodiments, the FD region 904 may be overlapped with the first photo sensing region, the second photo sensing region, the third photo sensing region and the fourth photo sensing region. Also, associated with the example pixel 902 is a source follower (SF) gate 906, a row select (RS) gate 908, and a reset (RST) gate 910.

FIG. 28 is a schematic top view of a first pixel 952 and a second pixel 972 according to some embodiments of the present disclosure. The first pixel 952 and the second pixel 972 are in a so-called 8T configuration. As illustrated the first pixel 952 has four sub-pixels (952-1, 952-2, 952-3, 952-4) and the second pixel 972 has four sub-pixels (972-1, 957-2, 972-3, 972-4). However, the disclosure is not limited thereto. In some alternative embodiments, the first pixel 952 may have three sub-pixels, or more than three sub-pixels depending on design requirement and the second pixel 972 may have three sub-pixels, or more than three sub-pixels depending on design requirement.

In the exemplary embodiment, the first sub-pixel 952-1 includes a first photo sensing region located within the substrate 940, and a first transfer gate (e.g., VTG 152) extending into the first photo sensing region. The second sub-pixel 952-2 includes a second photo sensing region located within the substrate 940, and a second transfer gate extending into the second photo sensing region. The third sub-pixel 952-3 includes a third photo sensing region located within the substrate 940, and a third transfer gate extending into the third photo sensing region. Similarly, the fourth sub-pixel 952-4 includes a fourth photo sensing region located within the substrate 940, and a fourth transfer gate extending into the fourth photo sensing region.

Similarly, in the exemplary embodiment, the first sub-pixel 972-1 includes a first photo sensing region located within the substrate 940, and a first transfer gate (e.g., VTG 152) extending into the first photo sensing region. The second sub-pixel 972-2 includes a second photo sensing region located within the substrate 940, and a second transfer gate extending into the second photo sensing region. The third sub-pixel 972-3 includes a third photo sensing region located within the substrate 940, and a third transfer gate extending into the third photo sensing region. Similarly, the fourth sub-pixel 972-4 includes a fourth photo sensing region located within the substrate 940, and a fourth transfer gate extending into the fourth photo sensing region.

In the exemplary embodiment, a floating diffusion (FD) region 954 is shared between the first photo sensing region, the second photo sensing region, the third photo sensing region and the fourth photo sensing region of the first pixel 952, and a FD region 974 is shared between the first photo sensing region, the second photo sensing region, the third photo sensing region and the fourth photo sensing region of the second pixel 972.

In this exemplary embodiment, the first pixel 952 has an associated RST gate 960, the second pixel 972 has an associated RST gate 976, and the first pixel 952 and the second pixel 972 share a SF gate 956 and an RS gate 958. The 8T configuration allows greater pixel density than the 4T configuration due to the sharing of SF gate 956 and the RS gate 958.

In some aspects, the techniques described herein relate to a method, including: providing a substrate having a front side and a back side; forming a recess in the substrate that extends from a front side surface on the front side to an interior region of the substrate; forming a sacrificial structure in the recess; forming an epitaxial grown silicon region in a top portion of the recess above the sacrificial structure and on the front side of the substrate; forming a CMOS image sensor (CIS) device on the front side of the substrate; removing the sacrificial structure thereby creating an opening; and forming a HK dielectric layer in the opening.

In some aspects, the techniques described herein relate to a method, wherein the sacrificial structure includes a liner layer and a high aspect ratio process (HARP) oxide layer.

In some aspects, the techniques described herein relate to a method, wherein forming an epitaxial grown silicon region in a top portion of the recess above the sacrificial structure and above the front side surface of the substrate further includes performing annealing operations on the substrate.

In some aspects, the techniques described herein relate to a method, wherein removing the sacrificial structure thereby creating the opening includes planarizing the back side of the substrate thereby exposing the sacrificial structure.

In some aspects, the techniques described herein relate to a method, wherein removing the sacrificial structure thereby creating the opening includes performing wet etching operations using hydrogen fluoride (HF).

In some aspects, the techniques described herein relate to a method, wherein the CIS device includes a transfer gate, a photo detector, and a floating diffusion region.

In some aspects, the techniques described herein relate to a semiconductor device, including: a photo detector in a substrate having a front side and a back side; a vertical transfer gate (VTG) on the front side of the substrate; a first deep trench isolation (DTI) feature disposed in the substrate on a side of the photo detector; an epitaxial layer in the substrate disposed above the first DTI feature on a first side of the VTG; and a p-well disposed in the substrate around the epitaxial layer.

In some aspects, the techniques described herein relate to a semiconductor device, further including a floating diffusion region including an n-type doped region formed in the substrate above the epitaxial layer.

In some aspects, the techniques described herein relate to a semiconductor device, wherein: the first DTI feature has a depth of approximately 2.5 micrometers to 3 micrometers; the epitaxial layer has a length of approximately 150 nm to approximately 300 nanometers (nm); the first DTI feature and epitaxial layer have a critical dimension (CD) of approximately 60 to approximately 90 nm; and the p-well has a width that is 0 to approximately 20 nm wider than the CD.

In some aspects, the techniques described herein relate to a semiconductor device, further including: a second DTI feature disposed in the substrate on a second side of the photo detector; a second epitaxial layer in the substrate disposed above the second DTI feature on a second side of the VTG; a second p-well disposed in the substrate around the second epitaxial layer; and an n-type doped region formed in the substrate above the second epitaxial layer.

In some aspects, the techniques described herein relate to a semiconductor device, further including: a second deep trench isolation (DTI) feature disposed in the substrate on a second side of the photo detector; a shallow trench isolation (STI) feature in the substrate above the second DTI feature on a second side of the VTG; and a second p-well disposed in the substrate around the STI feature.

In some aspects, the techniques described herein relate to a semiconductor device, wherein: the first DTI feature has a depth of approximately 2.5 micrometers to 3 micrometers; the second DTI feature has a depth of approximately 2.7 micrometers to 2.9 micrometers; the epitaxial layer has a length of approximately 150 nm to approximately 300 nanometers (nm); the STI feature has a length of approximately 100 nanometers (nm) to approximately 300 nm; the first DTI feature has a critical dimension (CD) of approximately 60 to approximately 90 nm; the second DTI feature has a second CD of approximately 110 nm to approximately 150 nm; the p-well has a width that is 0 to approximately 20 nm wider that the CD; and the second p-well has a width that is 0 to approximately 10 nm wider than the second CD.

In some aspects, the techniques described herein relate to a semiconductor device, wherein: the STI feature contacts the second DTI feature; the first DTI feature has a depth of approximately 2.5 micrometers to 3 micrometers; the second DTI feature has a depth of approximately 1.8 micrometers to 2.2 micrometers; the epitaxial layer has a length of approximately 150 nm to approximately 300 nanometers (nm); the STI feature has a length of approximately 100 nanometers (nm) to approximately 300 nm; the first DTI feature has a critical dimension (CD) of approximately 60 to approximately 90 nm; the second DTI feature has a second CD of approximately 110 nm to approximately 150 nm; the p-well has a width that is 0 to approximately 20 nm wider that the CD; and the second p-well has a width that is 0 to approximately 10 nm wider than the second CD.

In some aspects, the techniques described herein relate to a semiconductor device, further including an n-type doped region formed in the substrate adjacent to the STI feature.

In some aspects, the techniques described herein relate to a method of forming a pixel array, including: providing a substrate having a frontside and a backside; forming a recess in the frontside of the substrate for a front-side deep trench isolation (FDTI) feature; partially filling the recess with a sacrificial structure; forming an epitaxial grown silicon region in a top portion of the recess above the sacrificial structure and on the frontside of the substrate; forming a vertical transfer gate, photodetector, floating diffusion region, and p-well in the substrate; and completing the FDTI feature by replacing the sacrificial structure with a HK dielectric from the backside.

In some aspects, the techniques described herein relate to a method, wherein completing the FDTI feature includes completing the FDTI feature with a depth of approximately 2.5 micrometers to 3 micrometers.

In some aspects, the techniques described herein relate to a method, wherein forming the recess in the frontside of the substrate includes forming the recess in the frontside of the substrate with a critical dimension (CD) of approximately 60 to approximately 90 nm.

In some aspects, the techniques described herein relate to a method, wherein completing the FDTI feature includes: planarizing the backside of the substrate thereby exposing the sacrificial structure; removing the sacrificial structure via wet etching operations using hydrogen fluoride (HF) thereby creating an opening; and filling the opening with the HK dielectric.

In some aspects, the techniques described herein relate to a method, wherein: the pixel array is formed with a first pixel area configured to convert incident light into a first signal for a first pixel and a second pixel area configured to convert incident light into a second signal for a second pixel; forming the vertical transfer gate, photodetector, floating diffusion region, and p-well in the substrate includes forming a vertical transfer gate, photodetector, floating diffusion region, and p-well in the substrate in each of the first pixel area and the second pixel area; and the first pixel area and the second pixel area share a source follower device and a row select device.

In some aspects, the techniques described herein relate to a method, wherein each of the first pixel area and the second pixel area include a plurality of sub-pixel areas that share a floating diffusion region for a particular pixel and are configured to generate a sub-pixel signal for each sub-pixel area for the particular pixel, wherein the first signal is generated based on the sub-pixel signal generated for each sub-pixel area of the first pixel area and the second signal is generated based on the sub-pixel signal generated for each sub-pixel area of the second pixel area.

In some aspects, the techniques described herein relate to a pixel array having a first pixel area configured to convert incident light into a first signal for a first pixel and a second pixel area configured to convert incident light into a second signal for a second pixel, each of the first pixel area and the second pixel area including: a vertical transfer gate (VTG) disposed above a photo detector in a substrate having a front side and a back side; a front side formed deep trench isolation (FDTI) feature disposed in the substrate on a side of the photo detector; an epitaxial layer in the substrate formed above the FDTI feature on a first side of the VTG; and a p-well disposed in the substrate around the epitaxial layer.

While at least one exemplary embodiment has been presented in the foregoing detailed description of the disclosure, it should be appreciated that a vast number of variations exist. It should also be appreciated that the exemplary embodiment or exemplary embodiments are only examples, and are not intended to limit the scope, applicability, or configuration of the disclosure in any way. Rather, the foregoing detailed description will provide those skilled in the art with a convenient road map for implementing an exemplary embodiment of the disclosure. It being understood that various changes may be made in the function and arrangement of elements described in an exemplary embodiment without departing from the scope of the disclosure as set forth in the appended claims.

What is claimed is:

1. A method, comprising:
providing a substrate having a front side and a back side;
forming a recess in the substrate that extends from a front side surface on the front side to an interior region of the substrate;
forming a sacrificial structure in the recess;
forming an epitaxial grown silicon region in a top portion of the recess above the sacrificial structure and on the front side of the substrate;
forming a CMOS image sensor (CIS) device on the front side of the substrate;
removing the sacrificial structure thereby creating an opening; and
forming a HK dielectric layer in the opening.

2. The method of claim 1, wherein the sacrificial structure comprises a liner layer and a high aspect ratio process (HARP) oxide layer.

3. The method of claim 1, wherein forming an epitaxial grown silicon region in a top portion of the recess above the sacrificial structure and above the front side surface of the substrate further comprises performing annealing operations on the substrate.

4. The method of claim 1, wherein removing the sacrificial structure thereby creating the opening comprises planarizing the back side of the substrate thereby exposing the sacrificial structure.

5. The method of claim 1, wherein removing the sacrificial structure thereby creating the opening comprises performing wet etching operations using hydrogen fluoride (HF).

6. The method of claim 1, wherein the CIS device comprises a transfer gate, a photo detector, and a floating diffusion region.

7. A semiconductor device, comprising:
a photo detector in a substrate having a front side and a back side;
a vertical transfer gate (VTG) on the front side of the substrate;
a first deep trench isolation (DTI) feature disposed in the substrate on a side of the photo detector;
an epitaxial layer in the substrate disposed above the first DTI feature on a first side of the VTG; and
a p-well disposed in the substrate around the epitaxial layer.

8. The semiconductor device of claim 7, further comprising a floating diffusion region comprising an n-type doped region formed in the substrate above the epitaxial layer.

9. The semiconductor device of claim 7, wherein:
the first DTI feature has a depth of approximately 2.5 micrometers to 3 micrometers;
the epitaxial layer has a length of approximately 150 nm to approximately 300 nanometers (nm);
the first DTI feature and epitaxial layer have a critical dimension (CD) of approximately 60 to approximately 90 nm; and
the p-well has a width that is 0 to approximately 20 nm wider than the CD.

10. The semiconductor device of claim 7, further comprising:
a second DTI feature disposed in the substrate on a second side of the photo detector;
a second epitaxial layer in the substrate disposed above the second DTI feature on a second side of the VTG;
a second p-well disposed in the substrate around the second epitaxial layer; and
an n-type doped region formed in the substrate above the second epitaxial layer.

11. The semiconductor device of claim 7, further comprising:
a second deep trench isolation (DTI) feature disposed in the substrate on a second side of the photo detector;
a shallow trench isolation (STI) feature in the substrate above the second DTI feature on a second side of the VTG; and
a second p-well disposed in the substrate around the STI feature.

12. The semiconductor device of claim 11, wherein:
the first DTI feature has a depth of approximately 2.5 micrometers to 3 micrometers;
the second DTI feature has a depth of approximately 2.7 micrometers to 2.9 micrometers;
the epitaxial layer has a length of approximately 150 nm to approximately 300 nanometers (nm);
the STI feature has a length of approximately 100 nanometers (nm) to approximately 300 nm;
the first DTI feature has a critical dimension (CD) of approximately 60 to approximately 90 nm;
the second DTI feature has a second CD of approximately 110 nm to approximately 150 nm;
the p-well has a width that is 0 to approximately 20 nm wider that the CD; and
the second p-well has a width that is 0 to approximately 10 nm wider than the second CD.

13. The semiconductor device of claim 11, wherein:
the STI feature contacts the second DTI feature;
the first DTI feature has a depth of approximately 2.5 micrometers to 3 micrometers;
the second DTI feature has a depth of approximately 1.8 micrometers to 2.2 micrometers;
the epitaxial layer has a length of approximately 150 nm to approximately 300 nanometers (nm);
the STI feature has a length of approximately 100 nanometers (nm) to approximately 300 nm;
the first DTI feature has a critical dimension (CD) of approximately 60 to approximately 90 nm;
the second DTI feature has a second CD of approximately 110 nm to approximately 150 nm;
the p-well has a width that is 0 to approximately 20 nm wider that the CD; and
the second p-well has a width that is 0 to approximately 10 nm wider than the second CD.

14. The semiconductor device of claim 13, further comprising an n-type doped region formed in the substrate adjacent to the STI feature.

15. A method of forming a pixel array, comprising:
providing a substrate having a frontside and a backside;
forming a recess in the frontside of the substrate for a front-side deep trench isolation (FDTI) feature;
partially filling the recess with a sacrificial structure;
forming an epitaxial grown silicon region in a top portion of the recess above the sacrificial structure and on the frontside of the substrate;
forming a vertical transfer gate, photodetector, floating diffusion region, and p-well in the substrate; and
completing the FDTI feature by replacing the sacrificial structure with a HK dielectric from the backside.

16. The method of claim 15, wherein completing the FDTI feature comprises completing the FDTI feature with a depth of approximately 2.5 micrometers to 3 micrometers.

17. The method of claim 15, wherein forming the recess in the frontside of the substrate comprises forming the recess in the frontside of the substrate with a critical dimension (CD) of approximately 60 to approximately 90 nm.

18. The method of claim 15, wherein completing the FDTI feature comprises:
planarizing the backside of the substrate thereby exposing the sacrificial structure;
removing the sacrificial structure via wet etching operations using hydrogen fluoride (HF) thereby creating an opening; and
filling the opening with the HK dielectric.

19. The method of claim 15, wherein:
the pixel array is formed with a first pixel area configured to convert incident light into a first signal for a first pixel and a second pixel area configured to convert incident light into a second signal for a second pixel;
forming the vertical transfer gate, photodetector, floating diffusion region, and p-well in the substrate comprises forming a vertical transfer gate, photodetector, floating diffusion region, and p-well in the substrate in each of the first pixel area and the second pixel area; and
the first pixel area and the second pixel area share a source follower device and a row select device.

20. The method of claim 19, wherein each of the first pixel area and the second pixel area comprise a plurality of sub-pixel areas that share a floating diffusion region for a particular pixel and are configured to generate a sub-pixel signal for each sub-pixel area for the particular pixel, wherein the first signal is generated based on the sub-pixel signal generated for each sub-pixel area of the first pixel area and the second signal is generated based on the sub-pixel signal generated for each sub-pixel area of the second pixel area.
